(19) United States
(12) Patent Application Publication
(10) Pub. No.: US 2002/0131236 A1
(43) Pub. Date: Sep. 19, 2002

(54) CPU heat sink

(76) Inventor: Jen-Cheng Lin, Chung-Ho City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 09/809,045

(22) Filed: Mar. 16, 2001

(51) Int. Cl. H05K 7/20

(52) U.S. Cl. 361/709

(57) ABSTRACT

A heat sink has a base with pyramid shape, multiple channels latitudinally defined in the base and multiple cutouts longitudinally defined with respect to the base. The cutouts are diagonally defined through the fins on the base and orthogonal to the channels to provide a pathway for the circulation of air to allow the heat from the CPU to be carried away by the air.

### BACKGROUND OF THE INVENTION

1. Field of the Invention

The present invention relates to a heat sink, and more particularly to a heat sink for use with a central processing unit (CPU) to dissipate the heat generated by the CPU.

2. Description of Related Art

A heat sink dissipates the heat generated by a CPU. With reference to FIGS. 5 and 6, a conventional heat sink (50) has multiple parallel fins (52) and a pathway (53) defined between adjacent fins (52). The thickness of the heat sink (50) is fixed, such that when the heat sink (50) is mounted on top of the CPU, the heat sink (50) absorbs the heat through the base of the heat sink (50) that is in contact with the CPU. The heat is then transferred to the fins (52) by convection and radiated into the pathways (53). Thereafter, the heat will be carried away by the flow of air from a fan (not shown). This type of heat sink (50) has provided the desired heat dissipation effect for the conventional CPU. However, because newly developed, high speed CPUs being introduced to the market generate much more heat, the conventional heat sink (50) cannot meet the requirement any more. That is, the newly developed CPU, especially the central portion of the CPU, will radiate a dramatic amount of heat within seconds. With such a quick release of heat, the conventional heat sink cannot dissipate the heat quickly enough, which often leads to the damage of the CPU.

To overcome the shortcomings, the present invention tends to provide an improved CPU to mitigate and obviate the aforementioned problems.

### SUMMARY OF THE INVENTION

The primary objective of the invention is to provide an improved heat sink with longitudinal cutouts and latitudinal channels defined in and between the fins so that a perfect pathway for the circulation of air is thus created after the fan is mounted on top of the heat sink.

Another objective of the invention is to provide a heat sink with varying thickness so that the heat absorption capability provided by the heat sink to the CPU is able to focus on the thickest area that corresponds to the center of the CPU.

Other objects, advantages and novel features of the invention will become more apparent from the following detailed description when taken in conjunction with the accompanying drawings.

### BRIEF DESCRIPTION OF THE DRAWINGS

FIG. 1 is a perspective view of a heat sink in accordance with the present invention;

FIG. 2 is a cross sectional perspective view of the heat sink along line 2-2 in FIG. 1 showing the variation in thickness variation of the heat sink;

FIG. 3 is a cross sectional side plan view of the heat sink along line 3-3 in FIG. 1 showing that the depth of the cutouts in the fins gradually increase from the center of the heat sink;

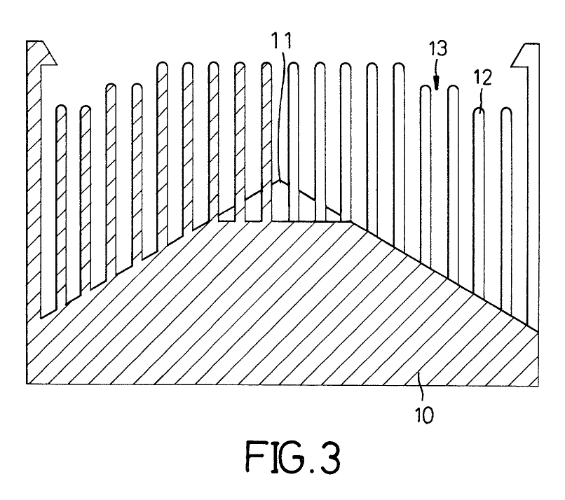

FIG. 4 is an operational exploded perspective view of the heat sink in FIG. 1 together with a CPU;

FIG. 5 is a perspective view of a conventional heat sink; and

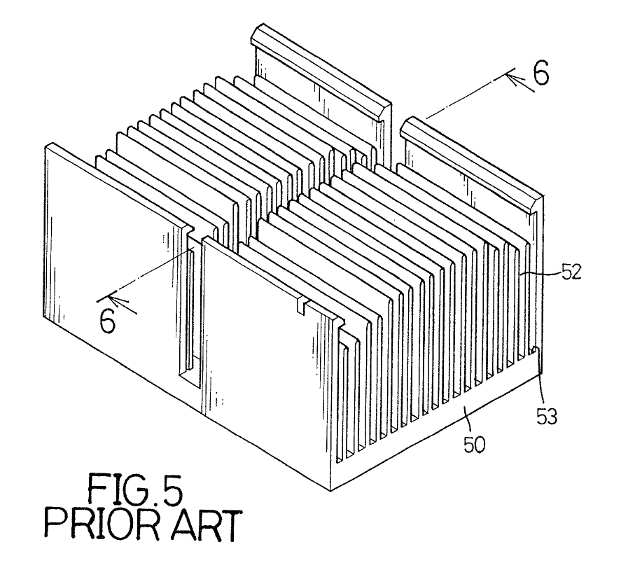

FIG. 6 is a cross sectional side plan view of the heat sink of FIG. 5.

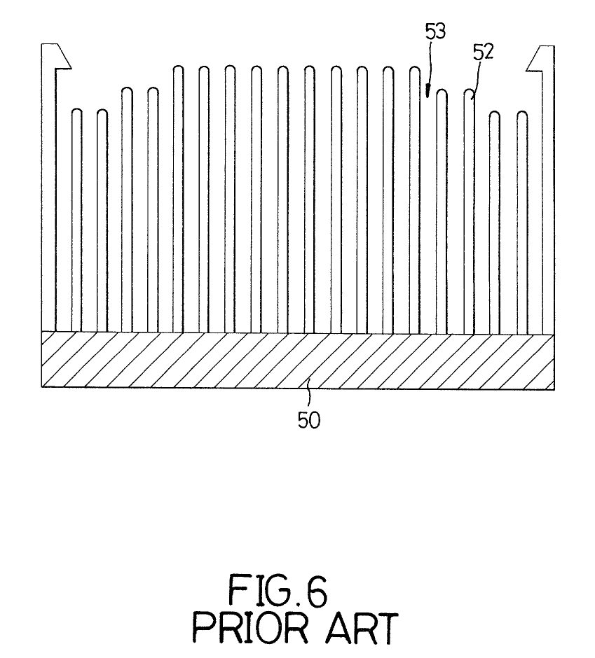

### DETAILED DESCRIPTION OF PREFERRED EMBODIMENT

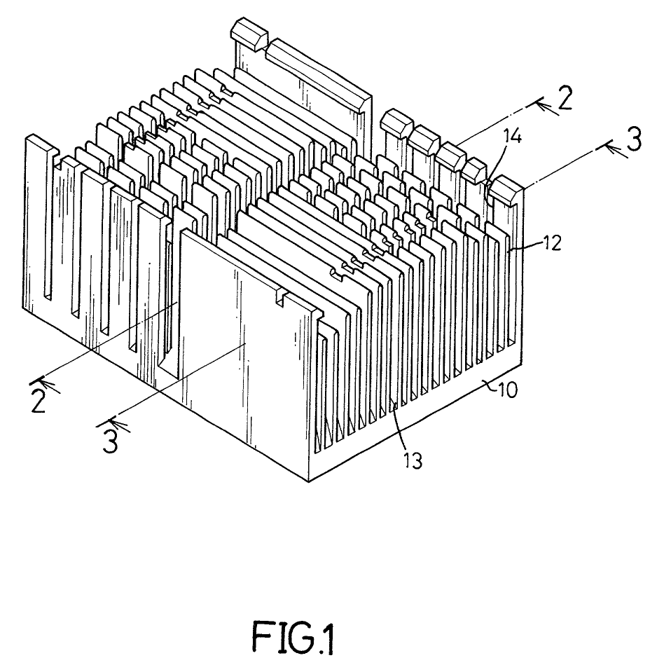

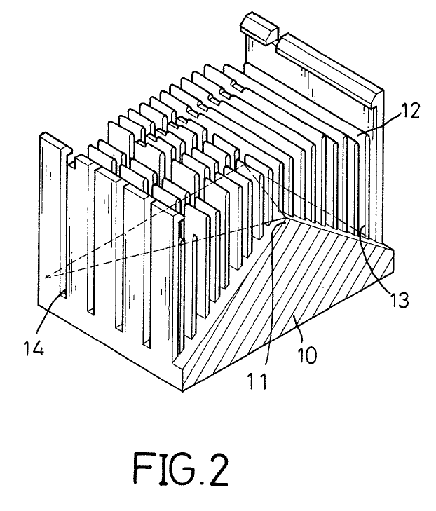

With reference to FIGS. 1 and 2, the heat sink (10) has a base (100) with a pyramidlike like shape, multiple fins (12) formed on the base (100), multiple channels (13) latitudinally defined between the fins (12) and cutouts (14) longitudinally defined in the fins (12) orthogonal to the channels (13).

The cutouts (14) are diagonally defined through the fins (12) and the channels (13) are defined between adjacent fins (12), such that the combination of the longitudinal cutouts (14) and the latitudinal channels (13) form a perfect pathway for the circulation of air by the fan (not shown). Because the natural air currents generated by the fan either swirl in a clockwise or counterclockwise direction depending on the rotation of the fan, the pathways provide a barrier free passage for the circulation of air and thus the heat dissipated is much greater.

Furthermore, the pyramid-shaped base (100) has an apex (11) that corresponds to the central portion of the CPU. With such a configuration, the thickest portion of the base (100) corresponds to the area of the CPU where the most heat is generated. This allows the absorbed heat to convect to more fins so that more heat can be radiated from the heat sink and CPU in a short period of time.

Furthermore, the cutouts (14) in the fins (12) has a depth gradually increasing from the center of the heat sink (10). That is, the apex (11), the thickest portion in the heat sink (10), has the cutouts (14) with the shortest length to correspond to the thickest portion of the heat sink (10).

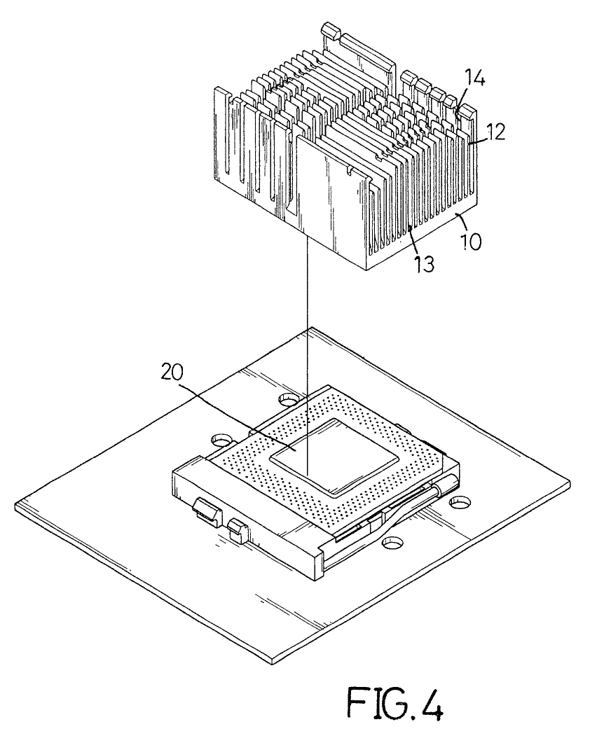

With reference to FIG. 4, when the heat sink (10) is in use, the heat sink (10) is securely mounted on top of a CPU (20) with the apex (11) corresponding to the central portion of the CPU (20) where the most heat is generated. Consequently, the heat generated by the CPU (20) will be absorbed by the thickest portion of the heat sink (10), and thereafter the channels (13) and cutouts (14) provide a perfect pathway for the circulation of air to allow the heat to be carried away by the circulating air.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat sink for a CPU, the heat sink comprising:
a base with multiple fins securely formed on a top of the base, multiple channels each defined between adjacent fins and multiple cutouts diagonally defined through the fins to be orthogonal to the channels.

2. The heat sink as claimed in claim 1, wherein the base has a pyramid shape and an apex at the thickest portion.

3. The heat sink as claimed in claim 1, wherein the channels are latitudinally defined in the base and the cutouts are longitudinally defined with respect to the base.

4. The heat sink as claimed in claim 2, wherein the channels are latitudinally defined in the base and the cutouts are longitudinally defined with respect to the base.

5. The heat sink as claimed in claim 1, wherein the cutouts have a tapered depth toward a center of the heat sink.

6. The heat sink as claimed in claim 2, wherein the cutouts have a tapered depth toward a center of the heat sink.

7. The heat sink as claimed in claim 3, wherein the cutouts have a tapered depth toward a center of the heat sink.

8. The heat sink as claimed in claim 4, wherein the cutouts have a tapered depth toward a center of the heat sink.
